(19) United States
(12) Patent Application Publication
(10) Pub. No.: US 2026/0313842 A1
(43) Pub. Date: Oct. 8, 2026

(54) DEEPLY COUPLED SYSTEM FOR ENERGY UTILIZATION, COOLING AND CARBON DIOXIDE ENERGY STORAGE IN DATA CENTER

(71) Applicant: Exax Energy Technology (Shenzhen) Co., Ltd, Shenzhen (CN)

(72) Inventors: Qiang Chen, Shenzhen (CN); Xiaoyong Wang, Shenzhen (CN)

(21) Appl. No.: 19/457,240

(22) Filed: Jan. 23, 2026

(30) Foreign Application Priority Data
Apr. 8, 2025 (CN) 2025104290567

(51) Int. Cl. H05K 7/20

(52) U.S. Cl. CPC H05K 7/20327; H05K 7/20827

(57) ABSTRACT

A deeply coupled system for energy utilization, cooling and carbon dioxide energy storage in a data center includes the data center, including: a power supply subsystem and a cooling and heat dissipation subsystem; and a carbon dioxide energy storage subsystem. The carbon dioxide energy storage subsystem is combined with a new energy power generation subsystem and/or a utility grid as a power supply source, coupled to the power supply subsystem, and configured to supply power to the data center. A working fluid circulation loop of the carbon dioxide energy storage subsystem is coupled to the cooling and heat dissipation subsystem, and a carbon dioxide working fluid extracted from the working fluid circulation loop serves as a cooling medium to cool and dissipate heat from the data center. The deeply coupled system can provide stable and uninterrupted power to the data center and realize optimized allocation of energy usage.

### CROSS-REFERENCE TO RELATED APPLICATION

This application claims priority to Chinese Patent Application No. 202510429056.7, filed on April 8, 2025, which is herein incorporated by reference in its entirety.

### TECHNICAL FIELD

The disclosure relates to the interdisciplinary field of carbon dioxide energy storage technologies and data center technologies, and more particularly to a deeply coupled system for energy utilization, cooling and carbon dioxide energy storage in a data center.

### BACKGROUND

Data centers serve as critical cornerstones of the modern information society, functioning as new infrastructure that enables digital transformation, intelligent upgrading, and integrated innovation. With the rapid development of digital economy and artificial intelligence in China, the computing power demand, computing power scale, and construction volume of data centers have increased annually, leading to a continuous rise in energy consumption of the data centers. The skyrocketing electricity demand of the data centers not only exerts tremendous pressure on the power grid but also poses severe environmental challenges. Specifically, the electricity consumption of the data centers primarily includes information technology (IT) equipment, cooling equipment, power supply and distribution systems, and lighting, etc. The escalating energy consumption and thermal management requirements of the data centers have resulted in a substantial increase in server heat generation. Existing research indicates that electricity consumption by the cooling equipment for cooling and heat dissipation accounts for approximately 40% of total data center energy consumption, making it the primary component of electricity usage. Currently, the power demand and energy consumption indicators of the data centers are increasingly becoming critical bottlenecks restricting their development. How to optimize the power supply and cooling and heat dissipation solutions for the data centers remains a persistent challenge the industry strives to address.

### SUMMARY

In view of the foregoing, the disclosure provides a deeply coupled system for energy utilization, cooling and carbon dioxide energy storage in a data center, which solves the problem of how to stably supply power to data centers and reduce the energy consumption of cooling and heat dissipation in data centers.

In order to achieve the above purposes, the disclosure adopts the following technical solutions.

A deeply coupled system for energy utilization, cooling and carbon dioxide energy storage in a data center includes: the data center and a carbon dioxide energy storage subsystem. The data center includes a power supply subsystem and a cooling and heat dissipation subsystem. The carbon dioxide energy storage subsystem is combined with at least one of a new energy power generation subsystem and a utility grid as a power supply source, coupled to the power supply subsystem, and configured to supply power to the data center.

A working fluid circulation loop of the carbon dioxide energy storage subsystem is coupled to the cooling and heat dissipation subsystem, and a carbon dioxide working fluid is configured to be extracted from the working fluid circulation loop as a cooling medium to cool and dissipate heat from the data center.

The working fluid circulation loop includes: a gas storage unit, an energy storage assembly, a liquid storage unit, and an energy release assembly connected sequentially in that order in a closed loop, and the working fluid circulation loop is coupled to the cooling and heat dissipation subsystem according to at least one of coupling modes (I) to (IV) as follows.

In the coupling mode (I), a first throttling mechanism and a gas-liquid separator are sequentially arranged in that order on a connection pipeline between the energy storage assembly and the liquid storage unit, a liquid phase output end of the gas-liquid separator is connected to the liquid storage unit, a gas phase output end of the gas-liquid separator is connected to a first cooling pipeline coupled to the cooling and heat dissipation subsystem, and gaseous carbon dioxide output from the gas-liquid separator is configured as the cooling medium to cool and dissipate the heat from the data center and be returned and input to the gas storage unit or the energy release assembly.

In the coupling mode (II), an output end of the energy storage assembly is provided with a second cooling pipeline coupled to the cooling and heat dissipation subsystem, a second throttling mechanism is disposed on the second cooling pipeline and configured to throttle and cool high-temperature and high-pressure gaseous carbon dioxide drawn from the energy storage assembly to obtain cooled gaseous carbon dioxide as the cooling medium, and the cooled gaseous carbon dioxide is configured to cool and dissipate the heat from the data center and be returned and input to the gas storage unit.

In the coupling mode (III), a connection pipeline between the energy release assembly and the gas storage unit is coupled to the cooling and heat dissipation subsystem, and gaseous carbon dioxide output from the energy release assembly is configured as the cooling medium to cool and dissipate the heat from the data center and be returned and input to the gas storage unit.

In the coupling mode (IV), a connection pipeline between the liquid storage unit and the energy release assembly is coupled to the cooling and heat dissipation subsystem; and liquid carbon dioxide output from the liquid storage unit is configured as the cooling medium to cool and dissipate the heat from the data center and be returned and input to the energy release assembly.

In an embodiment, a temperature of gaseous carbon dioxide stored in the gas storage unit is a first temperature; when the working fluid circulation loop of the carbon dioxide energy storage subsystem is coupled to the cooling and heat dissipation subsystem according to the coupling mode (III), the energy release assembly is controlled to reduce a temperature of the gaseous carbon dioxide at an output end of the energy release assembly to below a second temperature to improve energy release efficiency; the second temperature is less than the first temperature, and the gaseous carbon dioxide output from the energy release assembly is configured to be heated via heat exchange with the cooling and heat dissipation subsystem to reach above the first temperature, and be returned and input to the gas storage unit.

In an embodiment, in the coupling mode (IV), the connection pipeline between the liquid storage unit and the energy release assembly includes a first connection pipeline and a second connection pipeline; an end of the first connection pipeline is connected to the liquid storage unit, and another end of the first connection pipeline is connected to the energy release assembly; the second connection pipeline is coupled to the cooling and heat dissipation subsystem, and a first buffer tank and a third throttling mechanism are sequentially arranged in that order on the second connection pipeline between the liquid storage unit and the cooling and heat dissipation subsystem; and the liquid carbon dioxide output from the liquid storage unit is configured to be input to the first buffer tank, throttled and depressurized via the third throttling mechanism, input to the cooling and heat dissipation subsystem to cool and dissipate the heat from the data center, and then returned and input to the energy release assembly.

In an embodiment, the working fluid circulation loop is coupled to the cooling and heat dissipation subsystem by combining at least one of the coupling mode (I) and the coupling mode (II) with at least one of the coupling mode (III) and the coupling mode (IV).

When the carbon dioxide energy storage subsystem is in the energy storage operating condition, the carbon dioxide working fluid drawn from at least one of the coupling mode (I) and the coupling mode (II) serves as the cooling medium to cool and dissipate heat from the data center. When the carbon dioxide energy storage subsystem is in the energy release operating condition, the carbon dioxide working fluid drawn from at least one of the coupling mode (III) and the coupling mode (IV) serves as the cooling medium to cool and dissipate heat from the data center.

In an embodiment, the working fluid circulation loop is coupled to the cooling and heat dissipation subsystem by combining the coupling mode (I) and the coupling mode (IV).

In the coupling mode (I), the gaseous carbon dioxide output from the gas-liquid separator is configured as the cooling medium to cool and dissipate the heat from the data center and be returned and input to the energy release assembly.

A first valve is disposed on the first cooling pipeline between the gas-liquid separator and the cooling and heat dissipation subsystem, and a second valve is disposed on a connection pipeline between the liquid storage unit and the cooling and heat dissipation subsystem (i.e., the first connection pipeline).

In an embodiment, the cooling and heat dissipation subsystem includes a cooling circulation pipeline, and the carbon dioxide working fluid extracted from the working fluid circulation loop is configured to cool and dissipate the heat from the data center through a direct cooling mode or an indirect cooling mode. In the direct cooling mode, the carbon dioxide working fluid is configured to be injected into the cooling circulation pipeline, and directly exchange the heat with heat-generating equipment in the data center through the cooling circulation pipeline. In the indirect cooling mode, the cooling circulation pipeline is connected to an intermediate heat exchanger and circulates an intermediate heat exchange medium, the carbon dioxide working fluid is configured to exchange heat with the intermediate heat exchange medium in the intermediate heat exchanger, and the intermediate heat exchange medium is configured to exchange the heat with the heat-generating equipment in the data center through the cooling circulation pipeline.

In an embodiment, the data center further includes a fire protection subsystem, and the working fluid circulation loop of the carbon dioxide energy storage subsystem is further coupled to the fire protection subsystem, and the carbon dioxide working fluid in the working fluid circulation loop is configured as a fire extinguishing agent for the fire protection subsystem.

In an embodiment, the working fluid circulation loop is coupled to the fire protection subsystem according to at least one of a coupling mode (V) and a coupling mode (VI).

In the coupling mode (V), a first fire protection pipeline is connected from the gas storage unit and coupled to the fire protection subsystem, the gaseous carbon dioxide stored in the gas storage unit is configured as the fire extinguishing agent for the fire protection subsystem, and a third valve is disposed on the first fire protection pipeline.

In the coupling mode (VI), a second fire protection pipeline is connected from the liquid storage unit and coupled to the fire protection subsystem, liquid carbon dioxide stored in the liquid storage unit is configured as the fire extinguishing agent for the fire protection subsystem, and a fourth valve is disposed on the second fire protection pipeline.

In an embodiment, in the coupling mode (V), a drive fan and a gas pressure sensor are disposed on the first fire protection pipeline.

In an embodiment, in the coupling mode (VI), a second buffer tank is disposed on the second fire protection pipeline and between the liquid storage unit and the fourth valve.

In an embodiment, the power supply subsystem is a grid, including: grid power sources such as thermal/hydro/nuclear power plants, grid transmission lines, step-down/step-up substations, high-voltage/low-voltage distribution systems, and a dispatch center.

In an embodiment, the new energy power generation subsystem includes a photovoltaic power generation system, a wind power generation system, and a geothermal energy power generation system. The photovoltaic power generation system includes: photovoltaic arrays, a direct current combiner box, an inverter, a mounting system, grid-connected/off-grid control equipment, and an energy storage system. The wind power generation system includes: a wind turbine body, a tower, a generator, a power converter, a main control system, and grid-connection equipment. The geothermal energy power generation system includes: a geothermal well, a heat exchange system, a turbo-generator set, a reinjection system, and grid-connection equipment.

In an embodiment, the fire protection subsystem includes: a fire-extinguishing gas source, a blower, a sensor, a buffer tank, a valve, and a fire-fighting pipeline.

In an embodiment, the gas storage unit is a gas storage reservoir, including: a ground membrane, an inner foundation structure surrounding the outer side of the ground membrane, an outer foundation structure surrounding the outer side of the inner foundation structure, an inner membrane structure including an inner membrane and an inner cable net, an outer membrane structure enclosing the outer side of the inner membrane structure and including an outer membrane and an outer cable net, an air supply device for inflating the interlayer cavity, and an air exhaust device for discharging gas from the interlayer cavity. The edge of the inner membrane is fixed to the inner foundation structure, the ground membrane is connected to the inner membrane, the inner cable net is arranged on the outer surface of the inner membrane and fixedly connected to the inner foundation structure, an accommodation cavity is defined between the inner membrane and the ground membrane, and the inner membrane includes a metal layer. The edge of the outer membrane is fixed to the outer foundation structure, the outer cable net is arranged on the outer surface of the outer membrane and fixedly connected to the outer foundation structure, and an interlayer cavity is defined between the outer membrane and the inner membrane.

In an embodiment, the energy storage assembly includes a condenser and at least two compression energy storage sections. Each compression energy storage section includes a compressor and an energy storage heat exchanger. The compressor is used to compress carbon dioxide, and the condenser is used to condense carbon dioxide.

In an embodiment, the liquid storage unit includes a container configured to store liquid carbon dioxide.

In an embodiment, the energy release assembly includes an evaporator, an energy release cooler, and at least one expansion energy release section. Each expansion energy release section includes an expander and an energy release heat exchanger. The evaporator is configured to evaporate carbon dioxide, the expander is configured to release energy, and the energy release cooler is configured to cool the carbon dioxide entering the gas storage reservoir.

The embodiments of the disclosure provide the deeply coupled system for energy utilization, cooling and carbon dioxide energy storage in the data center with the following beneficial effects.

On one hand, the carbon dioxide energy storage subsystem is combined with at least one of the new energy (also referred to as new and renewable resources of energy) generation subsystem and the utility grid as the power supply source for the data center. During periods when new energy generation exceeds demand or during low electricity price periods, the carbon dioxide energy storage subsystem stores energy; during peak electricity price periods, the carbon dioxide energy storage subsystem releases energy. This arrangement supplies stable and uninterrupted electricity to the data center, balances energy supply and demand within the data center, realizes optimized allocation of energy utilization in the data center, and resolves issues of high electricity supply costs and high energy usage costs for the data center.

On the other hand, the carbon dioxide working fluid is drawn from the circulation loop of the carbon dioxide energy storage subsystem and configured as the cooling medium to cool and dissipate the heat from the data center. This reduces the refrigeration energy consumption and the cost investment of refrigeration system equipment in the data center. Furthermore, waste heat generated by the data center is recovered and utilized in the carbon dioxide energy storage subsystem, thereby improving the overall energy utilization efficiency of the deeply coupled system.

### BRIEF DESCRIPTION OF DRAWINGS

FIG. 1 illustrates a structural block diagram of a deeply coupled system according to an embodiment 1 of the disclosure.

FIGS. 2-7 illustrate structural diagrams of some coupling modes of the mutual coupling between a working fluid circulation loop of a carbon dioxide energy storage subsystem and a cooling and heat dissipation subsystem of a data center according to the embodiment 1 of the disclosure.

FIG. 8 illustrates a structural block diagram of a deeply coupled system according to an embodiment 2 of the disclosure.

FIG. 9 illustrates a structural block diagram of a deeply coupled system according to an embodiment 3 of the disclosure.

FIG. 10 illustrates a structural diagram of some coupling modes of the mutual coupling between a working fluid circulation loop of a carbon dioxide energy storage subsystem and a fire protection subsystem of a data center according to the embodiment 3 of the disclosure.

### DETAILED DESCRIPTION OF EMBODIMENTS

In order to clarify the purpose, technical solution, and advantages of the disclosure, the embodiments of the disclosure will be described in detail below in conjunction with the accompanying drawings. Examples of these exemplary embodiments are illustrated in the accompanying drawings. The embodiments of the disclosure shown in the drawings and described based on the drawings are merely exemplary and the disclosure is not limited to these embodiments.

It should be noted that the same or similar reference numbers in the accompanying drawings of the embodiments of the disclosure correspond to the same or similar components; In the description of the disclosure, it should be understood that if there are terms such as "up", "down", "left", "right" indicating orientation or positional relationships based on the orientation or positional relationships shown in the drawings, it is only for the convenience of describing the disclosure and simplifying the description, and does not indicate or imply that the device or component referred to must have a specific orientation, be constructed and operated in a specific orientation. Therefore, the terms used to describe positional relationships in the drawings are for illustrative purposes only and cannot be understood as limitations on the disclosure. For those skilled in the art, the specific meanings of the above terms can be understood according to specific situations.

Here, it should be noted that in order to avoid blurring the disclosure due to unnecessary details, only the structures and/or processing steps closely related to the solution according to the disclosure are shown in the accompanying drawings, and other details that are not closely related to the disclosure are omitted.

### Embodiment 1

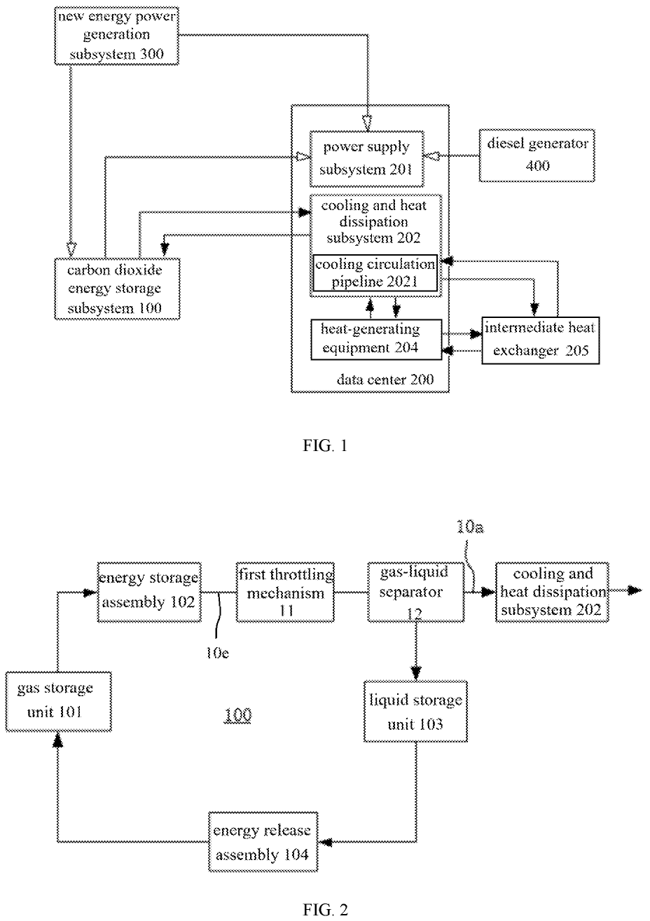

An embodiment of the disclosure provides a deeply coupled system for energy utilization, cooling and carbon dioxide energy storage in a data center 200. As shown in FIG. 1, the deeply coupled system includes a carbon dioxide energy storage subsystem 100 and the data center 200. The data center 200 includes a power supply subsystem 201 and a cooling and heat dissipation subsystem 202. The deeply coupled system in this embodiment mainly includes two aspects of coupling: a first aspect of coupling the carbon dioxide energy storage subsystem 100 with the power supply subsystem 201 to supply power to the data center 200; and a second aspect of coupling the carbon dioxide energy storage subsystem 100 with the cooling and heat dissipation subsystem 202 to supply cooling to the data center 200 and thereby cool and dissipate heat from the data center 200.

Specifically, referring to FIGS. 2-7, the carbon dioxide energy storage subsystem 100 mainly includes a gas storage unit 101, an energy storage assembly 102, a liquid storage unit 103, and an energy release assembly 104 connected sequentially in that order in a closed loop. The gas storage unit 101 is configured to store gaseous carbon dioxide at atmospheric pressure, and the liquid storage unit 103 is configured to store liquid carbon dioxide. Gaseous carbon dioxide flowing out from the gas storage unit 101 is converted into liquid carbon dioxide at a preset energy storage pressure through the energy storage assembly 102, and flows into the liquid storage unit 103, thereby completing energy storage in this process. Liquid carbon dioxide output from the liquid storage unit 103 releases energy and is converted into gaseous carbon dioxide at atmospheric pressure through the energy release assembly 104, and flows into the gas storage unit 101, thereby completing energy release and application in this process. Typically, during electricity consumption valley periods or by utilizing curtailed wind and solar power, the energy storage assembly 102 compresses and liquefies the gaseous carbon dioxide into the liquid carbon dioxide stored in the liquid storage unit 103, converting and storing energy in the form of compression energy and thermal energy; during electricity consumption peak periods, the energy release assembly 104 gasifies and expands the liquid carbon dioxide to perform work and generate electricity, thereby releasing the stored energy and converting the stored energy into electrical energy for use.

The specific composition and structure of the gas storage unit 101, the energy storage assembly 102, the liquid storage unit 103, and the energy release assembly 104 can refer to existing technologies, such as the technical solutions disclosed in existing Chinese patent documents with publication No.:CN116221616A, CN117628836A, and CN116857027A.

In a first aspect of the embodiment, referring to FIG. 1, the carbon dioxide energy storage subsystem 100 is combined with a new energy power generation subsystem 300 as a power supply source, coupled to the power supply subsystem 201, and configured to supply power to the data center 200.

The new energy power generation subsystem 300 is connected to the power supply subsystem 201 and the carbon dioxide energy storage subsystem 100. The carbon dioxide energy storage subsystem 100 is connected to the power supply subsystem 201. A part of the electric power generated by the new energy power generation subsystem 300 is transmitted directly to the power supply subsystem 201 to supply power to the data center 200, and another part of the electric power generated by the new energy power generation subsystem 300 is transmitted to the carbon dioxide energy storage subsystem 100 for energy storage. During periods when the power generation capacity of the new energy power generation subsystem 300 is abundant, the new energy power generation subsystem 300 supplies power to the data center 200; during electricity consumption peak periods or during periods when the power generation capacity of the new energy power generation subsystem 300 fluctuates and decreases, the carbon dioxide energy storage subsystem 100 releases energy to generate electricity and supplies power to the data center 200.

By utilizing a method combining carbon dioxide energy storage with new energy power generation to supply power to the data center 200, where new energy power generation serves as the primary power supply source, thus providing 24-hour stable and uninterrupted electricity to the data center, and utilizing green energy to reduce the operational costs of the data center 200 and enhance environmental benefits. Specifically, the new energy power generation subsystem 300 uses photovoltaic power generation or wind power generation. Taking the photovoltaic power generation as an example, during daytime when photovoltaic generation is abundant, the photovoltaic power generation supplies power to the data center 200 and provides electricity for the energy storage operation of the carbon dioxide energy storage subsystem 100, thereby completing electrical energy storage; when photovoltaic power generation decreases at night, the carbon dioxide energy storage subsystem 100 releases energy to generate electricity and supplies power to the data center 200. In this way, the deeply coupled system ensures continuous and stable power delivery to the data center 200.

In an embodiment, the power supply subsystem 201 is connected to a diesel generator 400 as a backup power source.

In a second aspect of the disclosure, referring to FIG. 1, the carbon dioxide energy storage subsystem 100 is coupled to the cooling and heat dissipation subsystem 202 of the data center 200 to provide cooling supply to the data center 200. Specifically, the working fluid circulation loop of the carbon dioxide energy storage subsystem 100 is coupled to the cooling and heat dissipation subsystem 202, and a carbon dioxide working fluid drawn from the working fluid circulation loop is configured as the cooling medium to cool and dissipate the heat from the data center 200.

Referring to FIGS. 2-7, the working fluid circulation loop of the carbon dioxide energy storage subsystem 100 is coupled to the cooling and heat dissipation subsystem 202 according to at least one of a coupling mode (I) to a coupling mode (IV) as follows.

As shown in FIG. 2, in the coupling mode (I), a first throttling mechanism 11 and a gas-liquid separator 12 are sequentially arranged in that order on a connection pipeline 10e between the energy storage assembly 102 and the liquid storage unit 103, a liquid phase output end of the gas-liquid separator 12 is connected to the liquid storage unit 103, a gas phase output end of the gas-liquid separator 12 is connected to a first cooling pipeline 10a coupled to the cooling and heat dissipation subsystem 202, and the gaseous carbon dioxide output from the gas-liquid separator 12 is configured as the cooling medium to be input to the cooling and heat dissipation subsystem 202 to cool and dissipate the heat from the data center 200 and be returned and input to the gas storage unit 101 or the energy release assembly 104. The first throttling mechanism 11 is, for example, a throttle valve.

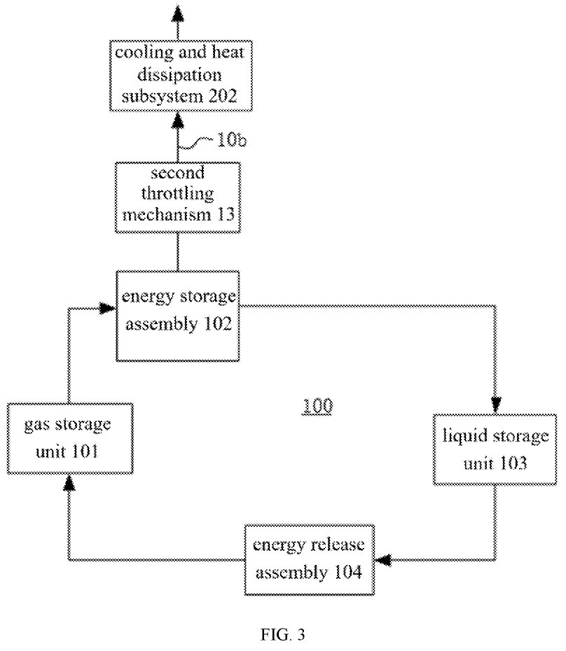

As shown in FIG. 3, in the coupling mode (II), an output end of the energy storage assembly 102 is provided with a second cooling pipeline 10b coupled to the cooling and heat dissipation subsystem 202, a second throttling mechanism 13 is disposed on the second cooling pipeline 10b and configured to throttle and cool high-temperature and high-pressure gaseous carbon dioxide drawn from the energy storage assembly 102 to obtain cooled gaseous carbon dioxide as the cooling medium, and the cooled gaseous carbon dioxide is configured to be input to the cooling and heat dissipation subsystem 202 to cool and dissipate the heat from the data center 200, and be returned and input to the gas storage unit 101. The second throttling mechanism 13 is, for example, a throttle valve.

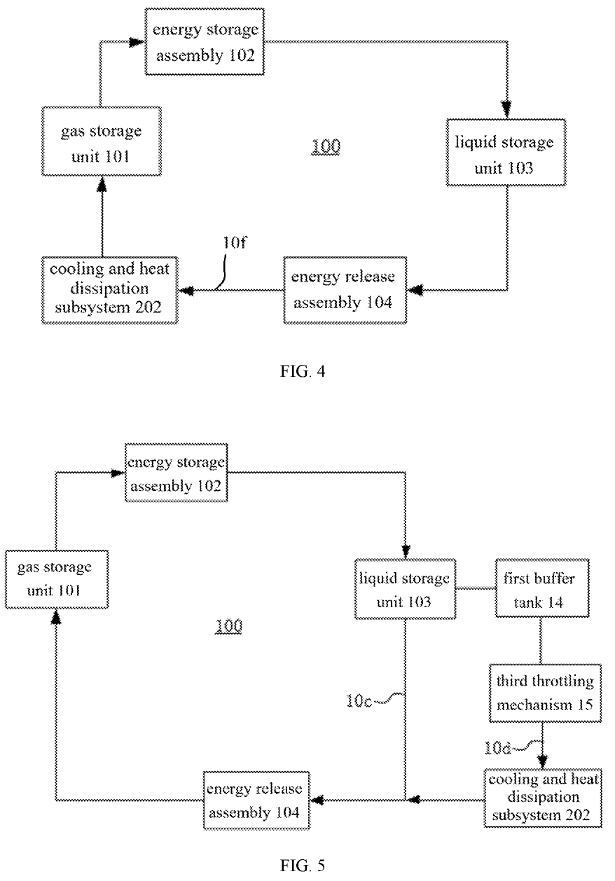

As shown in FIG. 4, in the coupling mode (III), a connection pipeline 10f between the energy release assembly 104 and the gas storage unit 101 is coupled to the cooling and heat dissipation subsystem 202, and gaseous carbon dioxide output from the energy release assembly 104 is configured as the cooling medium to be input to the cooling and heat dissipation subsystem 202 to cool and dissipate the heat from the data center 200 and be returned and input to the gas storage unit 101.

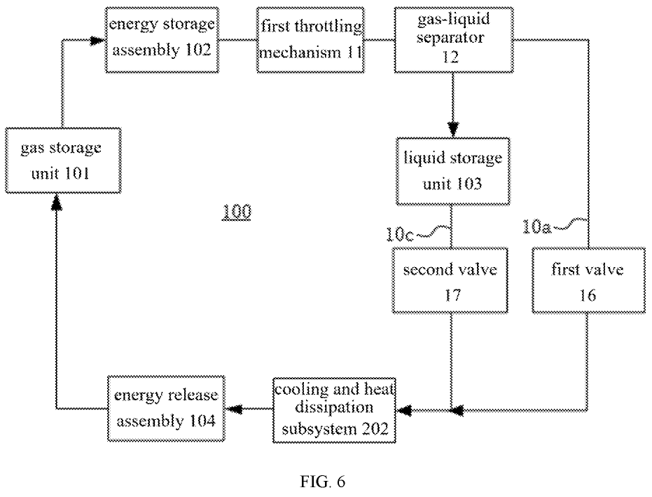

As shown in FIGS. 5-6, in the coupling mode (IV), a connection pipeline between the liquid storage unit 103 and the energy release assembly 104 is coupled to the cooling and heat dissipation subsystem 202; and liquid carbon dioxide output from the liquid storage unit 103 is configured as the cooling medium to be input to the cooling and heat dissipation subsystem 202 to cool and dissipate the heat from the data center 200 and be returned and input to the energy release assembly 104.

By using any one of the above coupling modes (I) to (IV), the working fluid circulation loop of the carbon dioxide energy storage subsystem 100 is coupled to the cooling and heat dissipation subsystem 202, and the carbon dioxide working fluid is extracted from the working fluid circulation loop to serve as the cooling medium to cool and dissipate heat from the data center 200. Compared with the existing use of air as a cooling medium for the data center 200, the use of carbon dioxide as the cooling medium achieves higher heat transfer efficiency. Specifically, comparing the heat transfer performance of carbon dioxide and air under normal temperature and pressure conditions shows that the thermal conductivity of air at normal temperature and pressure is 0.0165 watts per meter kelvin (W/m·K), while the thermal conductivity of carbon dioxide is 0.0262 W/m·K. The carbon dioxide has a higher thermal conductivity and possesses a higher volumetric heat capacity and a lower Prandtl number (Pr), resulting in faster boundary layer thermal diffusion and higher heat transfer efficiency, thereby improving the cooling and heat dissipation efficiency of the data center 200.

In the solution based on the coupling method (I), the gaseous carbon dioxide output from the energy storage assembly 102 is throttled and cooled by the first throttling mechanism 11 to form a gas-liquid two-phase flow, and the gaseous carbon dioxide separated from the gas-liquid two-phase flow by the gas-liquid separator 12 has a lower temperature, which improves the cooling and heat dissipation efficiency of the data center 200.

In the solution based on the coupling mode (II), high-temperature and high-pressure gaseous carbon dioxide drawn from the energy storage assembly 102 is throttled and cooled to serve as the cooling medium, and the gaseous carbon dioxide still maintains substantial pressure, enabling rapid cooling and heat dissipation for the data center 200, thereby improving efficiency.

In a conventional carbon dioxide energy storage subsystem 100, the temperature of the gaseous carbon dioxide stored in the gas storage unit 101 is set to a first temperature (typically above 20° C). If the temperature of the gaseous carbon dioxide stored in the gas storage unit 101 is lower than the first temperature, a preheating device needs to be provided on the connection pipeline between the gas storage unit 101 and the energy storage assembly 102 to preheat the carbon dioxide output from the gas storage unit 101 before the carbon dioxide is input to the energy storage assembly 102 for compression and energy storage. Therefore, to avoid the additional installation of a preheating device, typically during the energy release phase, the energy release assembly 104 needs to control the temperature of the gaseous carbon dioxide at its outlet to be above the first temperature when performing energy release. In the solution of this embodiment, when the working fluid circulation loop is coupled to the cooling and heat dissipation subsystem 202 according to the coupling mode (III), the energy release assembly 104 is controlled to reduce the temperature of the gaseous carbon dioxide at its outlet to below a second temperature to improve energy release efficiency. The gaseous carbon dioxide output from the energy release assembly 104 is heated through heat exchange with the cooling and heat dissipation subsystem 202 to reach above the first temperature, and then returned and input to the gas storage unit 101; and the second temperature is lower than the first temperature.

In the solution based on the coupling mode (III), on one hand, by reducing the temperature of the gaseous carbon dioxide at the outlet of the energy release assembly 104, the temperature difference between the carbon dioxide working fluid at the inlet and the carbon dioxide working fluid at the outlet is increased, thereby improving energy release efficiency; on the other hand, the low temperature of the gaseous carbon dioxide at the outlet of the energy release assembly 104 enables it to serve as a cooling medium to cool and dissipate heat from the data center 200, thereby improving the cooling and heat dissipation efficiency of the data center 200. Furthermore, the lower-temperature gaseous carbon dioxide output from the outlet of the energy release assembly 104 is heated through heat exchange with the cooling and heat dissipation subsystem 202 to meet the storage temperature requirement of the gas storage unit 101, so that no additional preheating device needs to be installed during the energy storage phase, realizing comprehensive utilization of the heat from the data center 200 and improving the overall energy utilization rate. Therefore, in a specific solution of this embodiment, the coupling between the working fluid circulation loop of the carbon dioxide energy storage subsystem 100 and the cooling and heat dissipation subsystem 202 at least includes the coupling mode (III), and the energy release assembly 104 is controlled to reduce the temperature of the gaseous carbon dioxide at its outlet to below the second temperature to improve energy release efficiency.

In the solution based on the coupling mode (IV), liquid carbon dioxide is drawn from the liquid storage unit 103 to serve as the cooling medium. The low temperature of the liquid carbon dioxide can improve the cooling and heat dissipation efficiency of the data center 200. Moreover, the liquid carbon dioxide absorbs heat from the data center 200, is warmed and evaporated, and is then input to the energy release assembly 104, thereby realizing comprehensive utilization of the heat from the data center 200 and improving the overall energy utilization rate.

When the working fluid circulation loop is coupled to the cooling and heat dissipation subsystem 202 according to the coupling mode (IV), in an exemplary solution, as shown in FIG. 5, the connection pipeline between the liquid storage unit 103 and the energy release assembly 104 includes a first connection pipeline 10c and a second connection pipeline 10d. An end of the first connection pipeline 10c is connected to the liquid storage unit 103, and another end of the first connection pipeline 10c is connected to the energy release assembly 104, to directly input the liquid carbon dioxide from the liquid storage unit 103 into the energy release assembly 104 for expansion and energy release. The second connection pipeline 10d is coupled to the cooling and heat dissipation subsystem 202, and a first buffer tank 14 and a third throttling mechanism 15 are sequentially arranged in that order on the second connection pipeline 10d between the liquid storage unit 103 and the cooling and heat dissipation subsystem 202. The liquid carbon dioxide output from the liquid storage unit 103 is configured to be input to the first buffer tank 14, throttled and depressurized via the third throttling mechanism 15, input to the cooling and heat dissipation subsystem 202 to cool and dissipate the heat from the data center 200, and then returned and input to the energy release assembly 104. In another alternative solution, as shown in FIG. 6, the liquid storage unit 103 is directly coupled to the cooling and heat dissipation subsystem 202 through the first connection pipeline 10c. The liquid carbon dioxide output from the liquid storage unit 103 is input into the cooling and heat dissipation subsystem 202 through the first connection pipeline 10c to cool and dissipate heat from the data center 200, and then returned and input to the energy release assembly 104. In an embodiment, the third throttling mechanism 15 is a throttle valve.

In an exemplary solution of the embodiment, the working fluid circulation loop is coupled to the cooling and heat dissipation subsystem 202 by combining at least one of the coupling mode (I) and the coupling mode (II) with at least one of the coupling mode (III) and the coupling mode (IV). When the carbon dioxide energy storage subsystem 100 is in the energy storage operating condition, the carbon dioxide working fluid drawn from at least one of the coupling mode (I) and the coupling mode (II) serves as the cooling medium to cool and dissipate heat from the data center 200; when the carbon dioxide energy storage subsystem 100 is in the energy release operating condition, the carbon dioxide working fluid drawn from at least one of the coupling mode (III) and the coupling mode (IV) serves as the cooling medium to cool and dissipate heat from the data center 200. It should be noted that when the working fluid circulation loop is coupled to the cooling and heat dissipation subsystem 202 by only one of the coupling modes (I) to (IV), if the carbon dioxide energy storage subsystem 100 is in certain operating conditions where no carbon dioxide working fluid can be drawn to cool and dissipate heat from the data center 200, traditional cooling equipment is used to assist in cooling and heat dissipation for the data center 200.

In an exemplary embodiment, as shown in FIG. 6, the working fluid circulation loop is coupled to the cooling and heat dissipation subsystem 202 by combining the coupling mode (I) with the coupling mode (IV). In the coupling mode (I), the gaseous carbon dioxide output from the gas-liquid separator 12 is configured as the cooling medium to be input to the cooling and heat dissipation subsystem 202 through the first cooling pipeline 10a to cool and dissipate the heat from the data center 200 and be returned and input to the energy release assembly 104. In the coupling mode (IV), the liquid storage unit 103 is directly coupled to the cooling and heat dissipation subsystem 202 through the first connection pipeline 10c. The liquid carbon dioxide output from the liquid storage unit 103 is configured to be input into the cooling and heat dissipation subsystem 202 through the first connection pipeline 10c to cool and dissipate heat from the data center 200 and then returned and input to the energy release assembly 104. A first valve 16 is provided on the first cooling pipeline 10a between the gas-liquid separator 12 and the cooling and heat dissipation subsystem 202, and a second valve 17 is provided on the first connection pipeline 10c between the liquid storage unit 103 and the cooling and heat dissipation subsystem 202.

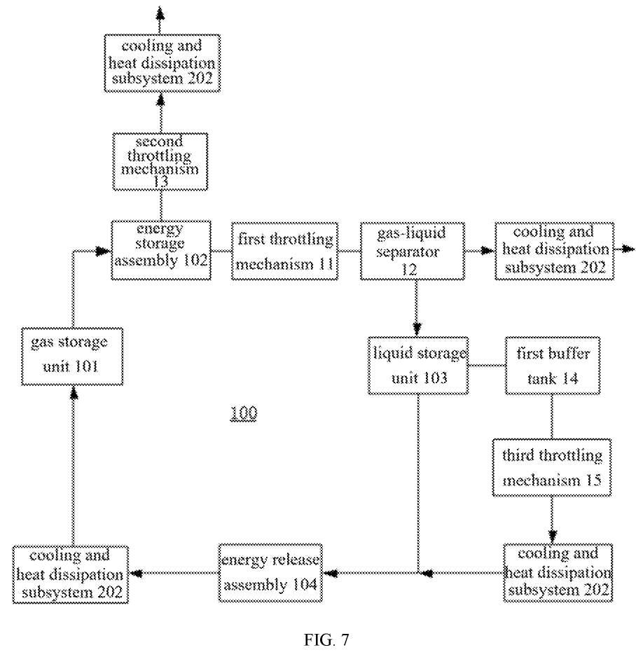

In an exemplary embodiment, as shown in FIG. 7, the working fluid circulation loop is coupled to the cooling and heat dissipation subsystem 202 by combining the coupling modes (I) to (IV), and the carbon dioxide working fluid is drawn from four different positions of the working fluid circulation loop respectively to cool and dissipate heat from the data center 200.

In a specific solution, the cooling and heat dissipation subsystem 202 includes a cooling circulation pipeline 2021. The carbon dioxide working fluid drawn from the working fluid circulation loop is configured to cool and dissipate heat from the data center 200 in a direct cooling mode or an indirect cooling mode. In the direct cooling mode, the carbon dioxide working fluid is configured to be injected into the cooling circulation pipeline 2021 and directly exchange heat with the heat-generating equipment 204 in the data center 200 through the cooling circulation pipeline 2021. In the indirect cooling mode, the cooling circulation pipeline 2021 is connected to an intermediate heat exchanger 205 and circulates an intermediate heat exchange medium. The carbon dioxide working fluid is configured to exchange heat with the intermediate heat exchange medium in the intermediate heat exchanger 205, and then the intermediate heat exchange medium is configured to exchange the heat with the heat-generating equipment 204 in the data center 200 through the cooling circulation pipeline 2021.

It should be noted that when the working fluid circulation loop is coupled to the cooling and heat dissipation subsystem 202 by combining two or more different coupling modes, different cooling circulation pipelines 2021 is provided in the cooling and heat dissipation subsystem 202, or the same cooling circulation pipeline 2021 is shared, according to actual needs.

### Embodiment 2

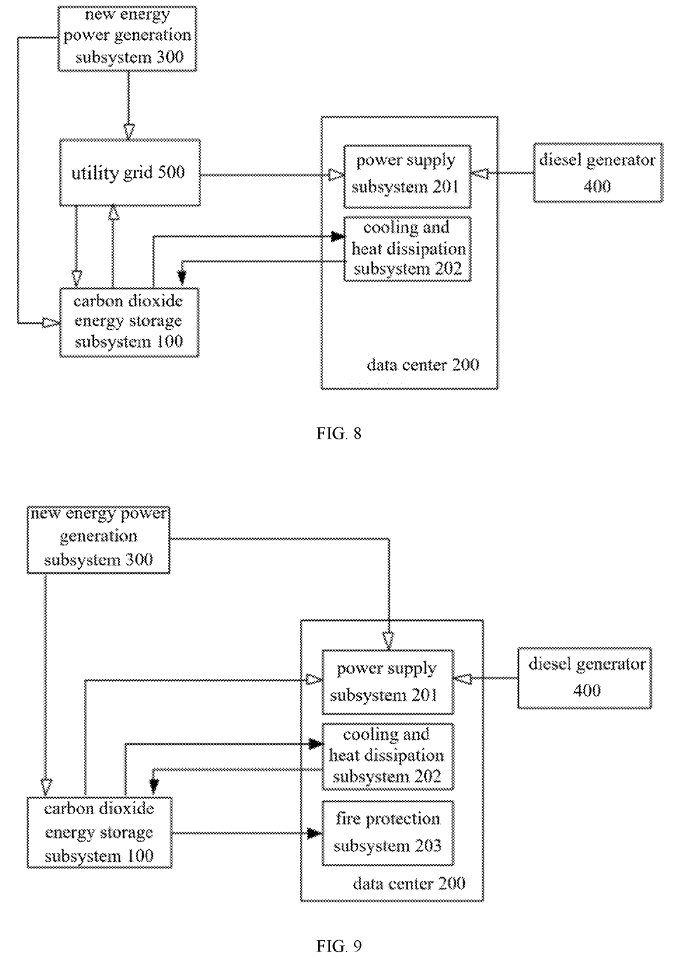

This embodiment provides a deeply coupled system for energy utilization, cooling and carbon dioxide energy storage in a data center. Compared with the embodiment 1, the manner in which the carbon dioxide energy storage subsystem 100 is coupled to the power supply subsystem 201 in this embodiment is different. With reference to FIG. 8, based on the embodiment 1, the deeply coupled system in this embodiment further includes a utility grid 500. The carbon dioxide energy storage subsystem 100 is in combination with the new energy power generation subsystem 300 and the utility grid 500 as a power supply source, and coupled to the power supply subsystem 201, to supply power to the data center 200.

As shown in FIG. 8, the new energy power generation subsystem 300 is connected to the utility grid 500 and the carbon dioxide energy storage subsystem 100. The electric power generated by the new energy power generation subsystem 300 is mainly transmitted to the utility grid 500 for grid injection; when curtailed power is generated, the curtailed portion is transmitted to the carbon dioxide energy storage subsystem 100 for energy storage. The carbon dioxide energy storage subsystem 100 is connected to the utility grid 500 and, subject to grid dispatch, stores energy during off-peak electricity consumption periods and releases energy during peak electricity consumption periods. The utility grid 500 is connected to the power supply subsystem 201, and the utility grid 500 is configured to supply power to the data center 200.

In this embodiment, by utilizing a combination of carbon dioxide energy storage, new energy power generation, and the utility grid 500 to supply power to the data center 200, the carbon dioxide energy storage subsystem 100 is employed to store energy during periods of abundant new energy generation or during off-peak electricity price periods, and to release energy during peak electricity price periods. This provides stable and uninterrupted power to the data center 200, balances the supply-demand balance of energy consumption of the data center 200, realizes optimized allocation of energy usage of the data center 200, and solves the problems of high power supply costs and high energy consumption costs in the data center 200.

In this embodiment, the manner in which the carbon dioxide energy storage subsystem 100 is coupled to the cooling and heat dissipation subsystem 202 of the data center 200 may refer to the embodiment 1, and thus will not be elaborated further.

### Embodiment 3

This embodiment provides a deeply coupled system for energy utilization, cooling and carbon dioxide energy storage of a data center. Based on the embodiment 1 or the embodiment 2, the deeply coupled system of this embodiment further includes a third aspect of coupling between the carbon dioxide energy storage subsystem 100 and the data center 200. Specifically, referring to FIG. 9 (which illustrates a further coupling based on the embodiment 1), the data center 200 is further provided with a fire protection subsystem 203. The working fluid circulation loop of the carbon dioxide energy storage subsystem 100 is also coupled to the fire protection subsystem 203, and the carbon dioxide working fluid in the working fluid circulation loop is configured as a fire extinguishing agent for the fire protection subsystem 203.

Specifically, the working fluid circulation loop of the carbon dioxide energy storage subsystem 100 is coupled to the fire protection subsystem 203 according to at least one of a coupling mode (V) and a coupling mode (VI).

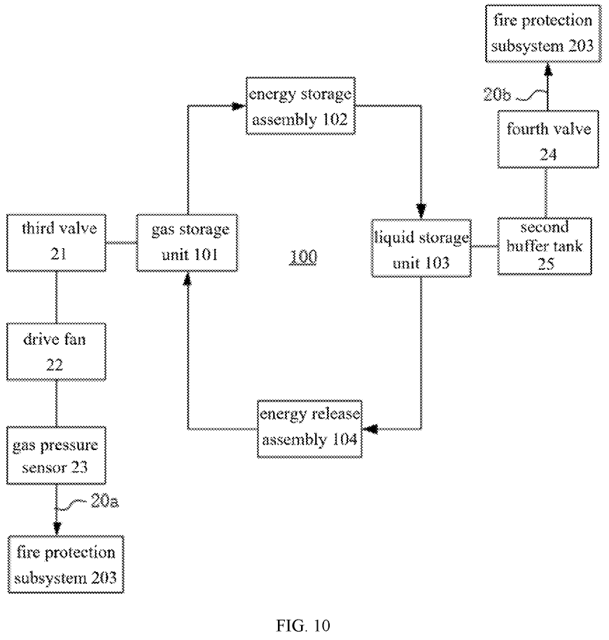

As shown in FIG. 10, in the coupling mode (V), a first fire protection pipeline 20a is connected from the gas storage unit 101 and coupled to the fire protection subsystem 203, the gaseous carbon dioxide stored in the gas storage unit 101 is configured as the fire extinguishing agent for the fire protection subsystem 203, and a third valve 21 is disposed on the first fire protection pipeline 20a. In an embodiment, a drive fan 22 and a gas pressure sensor 23 are disposed on the first fire protection pipeline 20a.

In the coupling mode (V), when the data center 200 detects a fire alarm signal, the fire extinguishing procedure is initiated. The third valve 21 is opened, and the drive fan 22 is activated to deliver carbon dioxide from the gas storage unit 101 as the fire extinguishing agent to the fire protection subsystem 203, reaching the fire scene in the data center 200. The carbon dioxide is sprayed according to a preset spraying intensity and duration. Specifically, the carbon dioxide is sprayed directly into the protected area at the designed intensity to uniformly fill the protected area or sprayed at the designed intensity toward the protected object for a certain period of time to achieve fire extinguishing. Additionally, the data center 200 is equipped with a monitoring system to supervise the fire extinguishing effect, ensuring that the fire can be effectively controlled. The gas pressure sensor 23 is configured to monitor the pressure of the carbon dioxide gas delivered to the fire protection subsystem 203.

As shown in FIG. 10, in the coupling mode (VI), a second fire protection pipeline 20b is connected from the liquid storage unit 103 and coupled to the fire protection subsystem 203, liquid carbon dioxide stored in the liquid storage unit 103 is configured as the fire extinguishing agent for the fire protection subsystem 203, and a fourth valve 24 is disposed on the second fire protection pipeline 20b. In an embodiment, in the coupling mode (VI), a second buffer tank 25 is disposed on the second fire protection pipeline 20b and between the liquid storage unit 103 and the fourth valve 24.

In the coupling mode (V), when the data center 200 detects a fire alarm signal, the fire extinguishing procedure is initiated. The inlet valve of the second buffer tank 25 is opened, and the fourth valve 24 is opened, allowing the liquid carbon dioxide in the liquid storage unit 103 to enter the second buffer tank 25. The liquid carbon dioxide is fed from the second buffer tank 25 into the fire protection subsystem 203 and reaches the fire scene in the data center 200. As the pressure of the carbon dioxide decreases, the carbon dioxide gas cools down and rapidly absorbs heat from the fire site, cooling the burning material. Meanwhile, the carbon dioxide gas released from the second buffer tank 25 disperses around the burning material, reducing the oxygen content in the ambient air, thereby stopping combustion and achieving fire extinguishing.

In this embodiment, by coupling the carbon dioxide energy storage subsystem 100 to the fire protection subsystem 203 of the data center 200 and drawing carbon dioxide working fluid from the working fluid circulation loop as the fire extinguishing agent for the fire protection subsystem 203, a highly efficient and environmentally friendly fire protection solution is established for the data center 200. When a fire is detected in the data center 200, this solution enables rapid and efficient fire extinguishing, improves the safety of the data center 200, reduces the investment cost of the fire extinguishing system of the data center 200, and saves costs.

In summary, the above embodiments of the disclosure provide the deeply coupled system for energy utilization, cooling and carbon dioxide energy storage in the data center 200. On one hand, the carbon dioxide energy storage subsystem 100 is combined with at least one of the new energy generation subsystem 300 and the utility grid 500 as the power supply source to supply power to the data center 200. During periods when new energy generation exceeds demand or during low electricity price periods, the carbon dioxide energy storage subsystem 100 stores energy; during peak electricity price periods, the carbon dioxide energy storage subsystem 100 releases energy. This arrangement supplies stable and uninterrupted electricity to the data center 200, balances energy supply and demand within the data center 200, realizes optimized allocation of energy utilization in the data center 200, and resolves issues of high electricity supply costs and high energy usage costs for the data center 200. On the other hand, the carbon dioxide working fluid is drawn from the circulation loop of the carbon dioxide energy storage subsystem 100 and configured as the cooling medium to cool and dissipate the heat from the data center 200. This reduces the refrigeration energy consumption and the cost investment of refrigeration system equipment in the data center 200. Furthermore, waste heat generated by the data center 200 is recovered and utilized in the carbon dioxide energy storage subsystem 100, thereby improving the overall energy utilization efficiency of the deeply coupled system. In a further solution, carbon dioxide working fluid is also drawn from the circulation loop of the carbon dioxide energy storage subsystem 100 to serve as the fire extinguishing agent for the fire protection subsystem 203 of the data center 200. This establishes a highly efficient and environmentally friendly fire protection solution for the data center 200, improves the safety of the data center 200, reduces the investment cost of the fire extinguishing system of the data center 200, and saves costs.

The above is only a specific implementation of the disclosure. It should be pointed out that for those skilled in this art, several improvements and embellishments can be made without departing from the principles of the disclosure. These improvements and embellishments should also be considered as the scope of protection of the disclosure.

What is claimed is:

1. A deeply coupled system for energy utilization, cooling and carbon dioxide energy storage in a data center, comprising:
the data center, comprising: a power supply subsystem and a cooling and heat dissipation subsystem; and
a carbon dioxide energy storage subsystem;
wherein the carbon dioxide energy storage subsystem is combined with at least one of a new energy power generation subsystem and a utility grid as a power supply source, coupled to the power supply subsystem, and configured to supply power to the data center;
wherein a working fluid circulation loop of the carbon dioxide energy storage subsystem is coupled to the cooling and heat dissipation subsystem, and a carbon dioxide working fluid is configured to be extracted from the working fluid circulation loop as a cooling medium to cool and dissipate heat from the data center;
wherein the working fluid circulation loop comprises: a gas storage unit, an energy storage assembly, a liquid storage unit, and an energy release assembly connected sequentially in that order in a closed loop, and the working fluid circulation loop is coupled to the cooling and heat dissipation subsystem by combining a coupling mode (I) and a coupling mode (III);
wherein in the coupling mode (I), a first throttling mechanism and a gas-liquid separator are sequentially arranged in that order on a connection pipeline between the energy storage assembly and the liquid storage unit, a liquid phase output end of the gas-liquid separator is connected to the liquid storage unit, a gas phase output end of the gas-liquid separator is connected to a first cooling pipeline coupled to the cooling and heat dissipation subsystem, and gaseous carbon dioxide output from the gas-liquid separator is configured as the cooling medium to cool and dissipate the heat from the data center and be returned and input to the gas storage unit or the energy release assembly;
wherein in the coupling mode (III), a connection pipeline between the energy release assembly and the gas storage unit is coupled to the cooling and heat dissipation subsystem, and gaseous carbon dioxide output from the energy release assembly is configured as the cooling medium to cool and dissipate the heat from the data center and be returned and input to the gas storage unit; and
wherein a temperature of gaseous carbon dioxide stored in the gas storage unit is a first temperature, the energy release assembly is controlled to reduce a temperature of the gaseous carbon dioxide at an output end of the energy release assembly to below a second temperature to improve energy release efficiency; the second temperature is less than the first temperature, and the gaseous carbon dioxide output from the energy release assembly is configured to be heated via heat exchange with the cooling and heat dissipation subsystem to reach above the first temperature, and be returned and input to the gas storage unit.

2. The deeply coupled system as claimed in claim 1, wherein the working fluid circulation loop is coupled to the cooling and heat dissipation subsystem by combining at least one of a coupling mode (II) and a coupling mode (IV) with the coupling mode (I) and the coupling mode (III);
wherein in the coupling mode (II), an output end of the energy storage assembly is provided with a second cooling pipeline coupled to the cooling and heat dissipation subsystem, a second throttling mechanism is disposed on the second cooling pipeline and configured to throttle and cool high-temperature and high-pressure gaseous carbon dioxide drawn from the energy storage assembly to obtain cooled gaseous carbon dioxide as the cooling medium, and the cooled gaseous carbon dioxide is configured to cool and dissipate the heat from the data center and be returned and input to the gas storage unit; and
wherein in the coupling mode (IV), a connection pipeline between the liquid storage unit and the energy release assembly is coupled to the cooling and heat dissipation subsystem; and liquid carbon dioxide output from the liquid storage unit is configured as the cooling medium to cool and dissipate the heat from the data center and be returned and input to the energy release assembly.

3. The deeply coupled system as claimed in claim 2, wherein in the coupling mode (IV), the connection pipeline between the liquid storage unit and the energy release assembly comprises a first connection pipeline and a second connection pipeline; an end of the first connection pipeline is connected to the liquid storage unit, and another end of the first connection pipeline is connected to the energy release assembly; the second connection pipeline is coupled to the cooling and heat dissipation subsystem, and a first buffer tank and a third throttling mechanism are sequentially arranged in that order on the second connection pipeline between the liquid storage unit and the cooling and heat dissipation subsystem; and the liquid carbon dioxide output from the liquid storage unit is configured to be input to the first buffer tank, throttled and depressurized via the third throttling mechanism, input to the cooling and heat dissipation subsystem to cool and dissipate the heat from the data center, and then returned and input to the energy release assembly.

4. The deeply coupled system as claimed in claim 2, wherein the working fluid circulation loop is coupled to the cooling and heat dissipation subsystem by combining the coupling mode (I), the coupling mode (III), and the coupling mode (IV);
wherein in the coupling mode (I), the gaseous carbon dioxide output from the gas-liquid separator is configured as the cooling medium to cool and dissipate the heat from the data center and be returned and input to the energy release assembly; and
wherein a first valve is disposed on the first cooling pipeline between the gas-liquid separator and the cooling and heat dissipation subsystem, and a second valve is disposed on a connection pipeline between the liquid storage unit and the cooling and heat dissipation subsystem.

5. The deeply coupled system as claimed in claim 1, wherein the cooling and heat dissipation subsystem comprises a cooling circulation pipeline, and the carbon dioxide working fluid extracted from the working fluid circulation loop is configured to cool and dissipate the heat from the data center through a direct cooling mode or an indirect cooling mode; and
wherein in the direct cooling mode, the carbon dioxide working fluid is configured to be injected into the cooling circulation pipeline, and directly exchange the heat with heat-generating equipment in the data center through the cooling circulation pipeline;
wherein in the indirect cooling mode, the cooling circulation pipeline is connected to an intermediate heat exchanger and circulates an intermediate heat exchange medium, the carbon dioxide working fluid is configured to exchange heat with the intermediate heat exchange medium in the intermediate heat exchanger, and the intermediate heat exchange medium is configured to exchange the heat with the heat-generating equipment in the data center through the cooling circulation pipeline.

6. The deeply coupled system as claimed in claim 1, wherein the data center further comprises a fire protection subsystem, and the working fluid circulation loop of the carbon dioxide energy storage subsystem is further coupled to the fire protection subsystem, and the carbon dioxide working fluid in the working fluid circulation loop is configured as a fire extinguishing agent for the fire protection subsystem.

7. The deeply coupled system as claimed in claim 6, wherein the working fluid circulation loop is coupled to the fire protection subsystem according to at least one of a coupling mode (V) and a coupling mode (VI);
wherein in the coupling mode (V), a first fire protection pipeline is connected from the gas storage unit and coupled to the fire protection subsystem, the gaseous carbon dioxide stored in the gas storage unit is configured as the fire extinguishing agent for the fire protection subsystem, and a third valve is disposed on the first fire protection pipeline; and
wherein in the coupling mode (VI), a second fire protection pipeline is connected from the liquid storage unit and coupled to the fire protection subsystem, liquid carbon dioxide stored in the liquid storage unit is configured as the fire extinguishing agent for the fire protection subsystem, and a fourth valve is disposed on the second fire protection pipeline.

8. The deeply coupled system as claimed in claim 7, wherein in the coupling mode (V), a drive fan and a gas pressure sensor are disposed on the first fire protection pipeline.

9. The deeply coupled system as claimed in claim 7, wherein in the coupling mode (VI), a second buffer tank is disposed on the second fire protection pipeline and between the liquid storage unit and the fourth valve.
